(19) United States
(12) Patent Application Publication
(10) Pub. No.: US 2026/0082669 A1
(43) Pub. Date: Mar. 19, 2026

(54) INTEGRATED CIRCUITS THAT INCLUDE GERMANIDE LAYER(S) IN BACKSIDE CONTACTS TO TRANSISTOR DEVICES FORMED IN THE INTEGRATED CIRCUIT (IC)

(71) Applicant: QUALCOMM Incorporated, San Diego, CA (US)

(72) Inventors: Abhishek Jain, San Diego, CA (US); Junjing Bao, San Diego, CA (US); John Jianhong Zhu, San Diego, CA (US); Giridhar Nallapati, San Diego, CA (US)

(21) Appl. No.: 18/884,848

(22) Filed: Sep. 13, 2024

(51) Int. Cl. H01L 29/49; H01L 21/283; H01L 21/324; H01L 27/088; H01L 29/06; H01L 29/16; H01L 29/423; H01L 29/66; H01L 29/775; H01L 29/786

(52) U.S. Cl. CPC H10D 64/668; H10D 84/83; H10P 14/40; H10P 95/90; H10D 30/014; H10D 30/43; H10D 30/6735; H10D 30/6757; H10D 62/121; H10D 62/83

(57) ABSTRACT

An IC includes a first source/drain region of a first transistor in a semiconductor substrate coupled to a first, frontside metallization layer through a metal contact and a low resistance layer (e.g., silicide layer) formed at a high temperature. A second source/drain region of a second transistor is coupled to a second, backside metallization layer(s) though a backside metal contact and a germanide layer. The germanide layer may be formed between the metal contact and a semiconductor material of the source/drain region at a lower temperature (e.g., 350° C.) than is used in the process to form low resistance (e.g., silicide) layers (e.g., 700° C.). Germanide layers reduce resistance of electrical paths between source/drain regions of transistors and backside metal contacts compared to silicide layers formed at the same lower temperatures and avoid the high temperatures that may cause damage to metallization layers on the integrated circuit (IC).

### TECHNICAL FIELD

The technology of the disclosure relates generally to integrated circuit (IC) chips and, more particularly, to electrical interconnects between transistor circuits in an IC chip and external contacts on both sides of the IC chip.

### BACKGROUND

As transistors become smaller, they can be more densely arranged on semiconductor substrates of integrated circuit (IC) chips, causing the metal interconnects that connect transistors to each other and to external contacts to be more congested. The metal interconnects include metal traces that extend horizontally in multiple layers of metallization on the front side (e.g., the side on which the transistors are formed) of the semiconductor substrates. The metal traces in different layers are connected by vertical interconnect accesses (vias) to form three-dimensional (3D) metal interconnects. One option for reducing congestion of the metal interconnects is to route functional logic and data signals to/from the transistors through the frontside metallization while providing power and ground connections to the transistors through the semiconductor substrate from the backside. Some of the metal interconnects that couple to transistor circuits are coupled to the source/drain regions of transistors, which are regions of doped semiconductor material. Thus, there is an interface of metal interconnects to the semiconductor material of the source/drain region, which may have a high electrical resistance.

To reduce the resistance of such interfaces, a silicide layer (e.g., a layer of material comprising both silicon and a metal) can be employed as the interface between the transistor source/drain regions and metal interconnects on the front side of the substrate. However, the silicide layer is formed in a process that requires a high temperature that cannot be tolerated during the processing of interconnect layers on the back side of the semiconductor substrate. Thus, the resistance of backside interconnects to the source/drain regions cannot be reduced using silicide layers.

### SUMMARY

Aspects disclosed herein include integrated circuits (ICs) that include germanide layer(s) in backside contacts to transistor device(s) formed in the IC. Related methods of fabricating ICs with germanide layers in the backside contacts are also disclosed. In back-end-of-line (BEOL) processing, wherein front side metallization layers are formed, it may be desired to also include a metallization layer(s) on a back side of an IC, opposite to the front side of the IC to provide the benefit of additional routing area, such as for power routing. A low resistance interface may be provided between the transistor devices and the front side metal contacts by forming a silicide layer in a high-temperature process (e.g., >=700 C) on the semiconductor material of a transistor source/drain region. Lower resistance interfaces are of particular importance for P-type semiconductor material (P)-channel or P-type transistors in which current flow tends to be lower than in similarly sized N-channel or N-type transistors. The front side metallization layers can thereafter be formed on the front side of the IC in a lower temperature process to avoid metal diffusion. However, when the back side metallization layer(s) are to be formed, silicide layers cannot be formed to reduce contact resistance between the source/drain regions and metal contacts on the backside of the semiconductor substrate in a higher temperature process without risking damaging the front side metallization layers.

In this regard, in exemplary aspects, an IC is disclosed herein that includes a first source/drain region of a first transistor in a semiconductor substrate coupled to a first, frontside metallization layer through a metal contact and a low resistance layer (e.g., silicide layer) that may have to be formed at a high temperature. A second source/drain region of a second transistor is coupled to a second, backside metallization layer(s) though a backside metal contact and a germanide layer. The germanide layer may be formed between the metal contact and a semiconductor material of the source/drain region at a lower temperature (e.g., 350° C.) than is used in the process to form low-resistance silicide layers (e.g., 700° C.). Thus, germanide layers reduce resistance of electrical paths between source/drain regions of transistors and backside metal contacts compared to silicide layers formed at the same lower temperatures. In this manner, drive currents may be increased without the need to subject the IC to high temperatures that may cause damage, such as during fabrication of metallization layers in the IC. In some examples, a metal contact between a source/drain region is formed in a void that is longitudinally aligned with the source/drain region.

In this regard, in one aspect, an IC is disclosed. The IC includes a semiconductor substrate having a first side and a second side. The IC further includes a first transistor and a second transistor formed in the semiconductor substrate, each including a first source/drain region, a second source/drain region, and a channel region between the first source/drain region and the second source/drain. The IC further includes a first metal contact adjacent to the first side of the semiconductor substrate and electrically coupled to the first source/drain region of the first transistor, a second metal contact extending between the second side of the semiconductor substrate and the first source/drain region of the second transistor, and a germanide layer disposed between the second metal contact and the first source/drain region of the second transistor.

In another aspect, a method of manufacturing an IC is disclosed. The method includes forming a semiconductor substrate having a first side and a second side. The method further includes forming a first transistor and a second transistor in the semiconductor substrate, each including a first source/drain region, a second source/drain region, and a channel region between the first source/drain region and the second source/drain region. The method further includes forming a first metal contact adjacent to the first side of the semiconductor substrate and electrically coupled to the first source/drain region of the first transistor, forming a second metal contact extending between the second side of the semiconductor substrate and the first source/drain region of the second transistor, and forming a germanide layer disposed between the second metal contact and the first source/drain region of the second transistor.

### BRIEF DESCRIPTION OF THE DRAWINGS

FIG. 1 is a cross-sectional side view of an integrated circuit (IC), including transistors in a semiconductor layer coupled to frontside metal interconnects through a first low resistance interface, and to backside metal interconnects through a low resistance germanide layer;

FIGS. 2A and 2B are cross-sectional side views of a higher resistance contact between a backside interconnect and a source/drain region of a transistor without a germanide layer;

FIGS. 3A and 3B are cross-sectional side views of a first example of a field-effect transistor (FET) that includes an exemplary lower resistance contact between a backside interconnect and a source/drain region of a transistor, including a germanide layer;

FIG. 4 is a cross-sectional side view of a second example of a FET that includes the exemplary lower resistance contact provided by a germanide layer between a backside interconnect and a source/drain region of a transistor, as shown in FIGS. 3A and 3B;

FIG. 5 is a flowchart of an exemplary process for manufacturing the IC of FIG. 1;

FIGS. 6A-6C are a flowchart of an exemplary process for manufacturing a transistor in an IC that includes transistors in a semiconductor layer coupled to frontside metal interconnects through a first low resistance interface, and to backside metal interconnects through a low resistance germanide layer, including but not limited to the IC in FIG. 1;

FIGS. 6D-1-6D-2 are a flowchart of an alternative exemplary process for manufacturing the transistor in an IC that includes transistors in a semiconductor layer coupled to frontside metal interconnects through a first low resistance interface, and to backside metal interconnects through a low resistance germanide layer, including but not limited to the IC in the IC of FIG. 1;

FIGS. 7A-7H are illustrations of the exemplary stages of the process for manufacturing a transistor as described in FIGS. 6A-6H;

FIGS. 7D-1-7G-1 are illustrations of the exemplary stages of the alternative manufacturing process illustrated in FIGS. 6D-1 and 6D-2;

FIG. 8 is a block diagram of an exemplary IC that includes frontside metal interconnects coupled to transistor source/drain regions through lower-resistance layers and backside metal contacts coupled to the transistor source/drain regions through germanide layers to reduce resistance of an interface to backside metal contacts; and

FIG. 9 is a block diagram of an exemplary wireless communication device that includes radio-frequency (RF) components that can be disposed on ICs, including frontside metal interconnects coupled to transistor source/drain regions through lower-resistance layers and backside metal contacts coupled to the transistor source/drain regions through germanide layers to reduce resistance of an interface to backside metal contacts.

### DETAILED DESCRIPTION

With reference now to the drawing figures, several exemplary aspects of the present disclosure are described. The word “exemplary” is used herein to mean “serving as an example, instance, or illustration. ” Any aspect described herein as “exemplary” is not necessarily to be construed as preferred or advantageous over other aspects.

Aspects disclosed herein include integrated circuits (ICs) that include germanide layer(s) in backside contacts to transistor device(s) formed in the IC. Related methods of fabricating ICs with germanide layers in the backside contacts are also disclosed. In back-end-of-line (BEOL) processing, wherein front side metallization layers are formed, it may be desired to also include a metallization layer(s) on a back side of an IC, opposite to the front side of the IC, to provide the benefit of additional routing area, such as for power routing. A low resistance interface may be provided between the transistor devices and the front side metal contacts by forming a silicide layer in a high temperature process (e.g., >=700 C) on the semiconductor material of a transistor source/drain region. Lower resistance interfaces are of particular importance for P-type semiconductor material (P)-channel or P-type transistors in which current flow tends to be lower than in similarly sized N-channel or N-type transistors. The front side metallization layers can thereafter be formed on the front side of the IC in a lower temperature process to avoid metal diffusion. However, when the back side metallization layer(s) are to be formed, silicide layers cannot be formed to reduce contact resistance between the source/drain regions and metal contacts on the backside of the semiconductor substrate in a higher temperature process without risking damaging the front side metallization layers.

In this regard, in exemplary aspects, an IC is disclosed herein that includes a first source/drain region of a first transistor in a semiconductor substrate coupled to a first, frontside metallization layer through a metal contact and a low resistance layer (e.g., silicide layer) that may have to be formed at a high temperature. A second source/drain region of a second transistor is coupled to a second, backside metallization layer(s) though a backside metal contact and a germanide layer. The germanide layer may be formed between the metal contact and a semiconductor material of the source/drain region at a lower temperature (e.g., 350° C.) than is used in the process to form low resistance silicide layers (e.g., 700° C.). Thus, germanide layers reduce resistance of electrical paths between source/drain regions of transistors and backside metal contacts compared to silicide layers formed at the same lower temperatures. In this manner, drive currents may be increased without the need to subject the IC to high temperatures that may cause damage, such as during fabrication of metallization layers in the IC. In some examples, a metal contact between a source/drain region is formed in a void that is longitudinally aligned with the source/drain region.

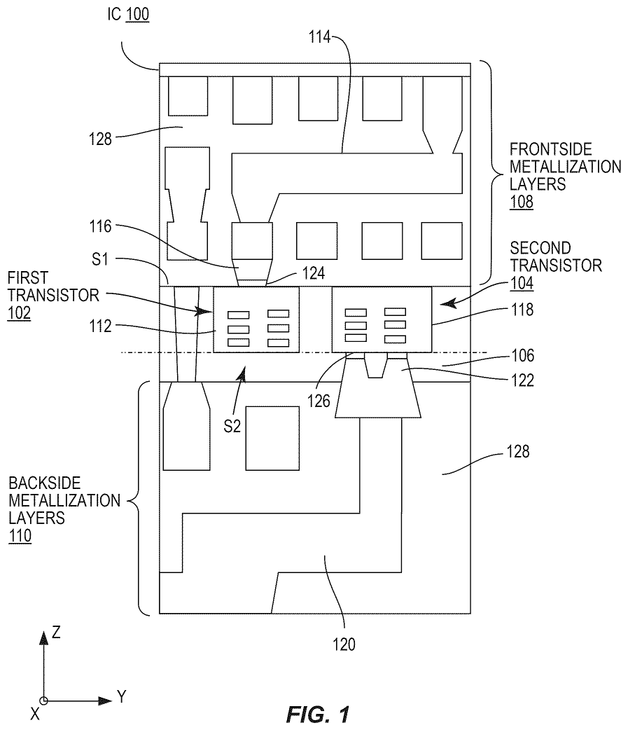

FIG. 1 is a cross-sectional side view of an exemplary IC 100 including first and second transistors 102 and 104 formed in a semiconductor substrate 106 with frontside metallization layers 108 on a first, front side S1 and backside metallization layers 110 on a second, back side S2. The first transistor 102 includes a first source/drain region 112 that is coupled to a frontside metal interconnect 114 through a first metal contact 116. The second transistor 104 includes a second source/drain region 118 coupled to a backside metal interconnect 120 through a second metal contact 122.

The first source/drain region 112 of the first transistor 102 is coupled to the first metal contact 116 through a first layer 124 to reduce an interface resistance that would otherwise exist between the first source/drain region 112 and the frontside metal interconnect 114. The first layer 124 may be a silicide layer and is described herein as a silicide layer 124 but the first layer 124 is not limited to being a silicide layer. Formation of the first layer 124 is achieved by way of a process (e.g., annealing) in which the IC 100 is subjected to high temperatures. In the example of the silicide layer 124, the high temperatures are employed to diffuse a metal into silicon. However, the temperatures to which the IC 100 is exposed in such processes may be in the range of 700 degrees Celsius (700° C.) or higher to obtain a desired result. This process is completed before the formation of the frontside metallization layers 108, which may be damaged if they were subjected to such high temperatures. Attempts to form silicide layers on the second source/drain region 118 on the second side S2 of the semiconductor substrate 106 at lower temperatures to avoid damage to the frontside metallization layers do not sufficiently lower the resistance of the interface.

In an exemplary aspect, the IC 100 includes a germanide layer 126 disposed between the second source/drain region 118 and the second metal contact 122. A germanide layer 126 may be formed at a much lower temperature, such as below 400 degrees Celsius (400° C.), than the silicide layer 124 and provides a reduction in resistance that is comparable to the benefit of the silicide layer 124. In some examples, the germanide layer 126 may be formed at a temperature less than about 350 degrees Celsius (350° C.), which the frontside metallization layers 108 can tolerate without damage.

The germanide layer 126 may be formed of germanium (Ge) and an appropriate metal, such as nickel (Ni). In the low-temperature process noted above, the nickel diffuses into the germanium to form the germanide layer 126, as described more fully below. The metal contacts 116 and 122 may be formed of cobalt, molybdenum, or tungsten, for example, which is further coupled to the frontside metallization layers 108 and backside metallization layers 110. The metallization layers 108 and 110 may be formed of copper or another appropriate conductive material disposed in layers that are separated by a dielectric material 128.

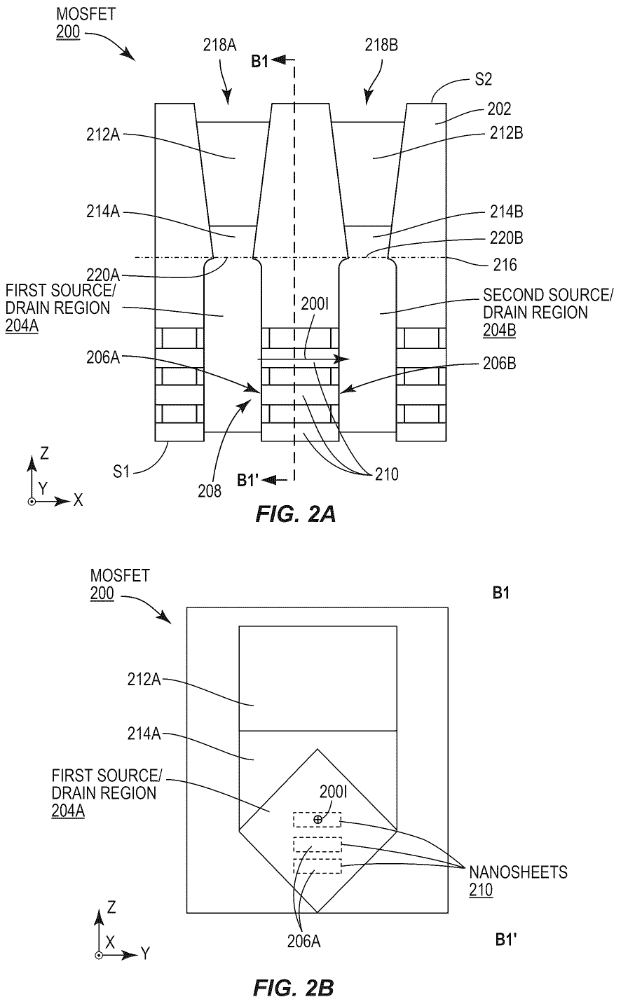

FIG. 2A is a cross-sectional side view of a metal-oxide semiconductor field effect transistor (MOSFET) 200 formed in a semiconductor substrate 202. A side view of the cross-section B1-B1′ of the MOSFET 200 is shown in FIG. 2B. The MOSFET 200 includes a first source/drain region 204A and a second source/drain region 204B, which are disposed at respective ends 206A, 206B of a channel region 208 that includes a plurality of nanosheets 210. The view in FIG. 2A is in a first direction (X-axis direction) orthogonal to current flow 200I in a second (Y-axis) direction through the plurality of nanosheets 210. The current may flow from the first source/drain region 204A to the second source/drain region 204B, or in the reverse direction, depending on which of the source/drain regions 204A, 204B is configured as the source and which is the drain in a circuit configuration.

In the view in FIG. 2A, the MOSFET 200 is in an inverted orientation, such that a first side S1 of the semiconductor substrate 202 is on the bottom in the view shown. It should be understood that frontside metallization layers are formed on the first side S1 but are not shown here. FIG. 2A is provided to illustrate backside metal contacts 212A, 212B and silicide layers 214A, 214B that are not formed at the higher temperature range employed in frontend processing. As a result of formation via a lower temperature process, an electrical resistance through the backside metal contacts 212A, 212B and silicide layers 214A, 214B to the source/drain regions 204A, 204B is higher than a resistance of an electrical path through a comparable frontside interconnect formed at the range of 700° C.

Line 216 indicates a point of intersection between the source/drain regions 204A, 204B and their respective silicide layers 214A, 214B. The silicide layers 214A, 214B and the metal contacts 212A, 212B are formed in voids 218A, 218B that are formed in a second side S2 of the semiconductor substrate 202, for example by etching or another subtractive process. Openings 220A, 220B are formed where the voids 218A, 218B meet the source/drain regions 204A, 204B at the line 216.

FIG. 2B is a side view of a cross-section B1-B1′ of the MOSFET 200 in FIG. 2A that extends through the first source/drain region 204A in the first direction (X-axis) and a third direction (Z-axis). FIG. 2B is a view in the second direction (Y-axis) parallel to the current flow 200I that flows through the nanosheets 210. As shown in FIG. 2B, the first source/drain region 204A may be epitaxially grown on the end 206A of the nanosheets 210. The silicide layer 214A formed on the first source/drain region 204A provides an interface to the metal contact 212A. Although such an interface may have lower resistance than it would if the metal contact 212A was disposed directly on the first source/drain region 204A, the silicide layer 214A could not be annealed at the high temperature to avoid damaging the MOSFET 200 and does not provide a sufficiently low resistance interface due to being annealed at a much lower temperature.

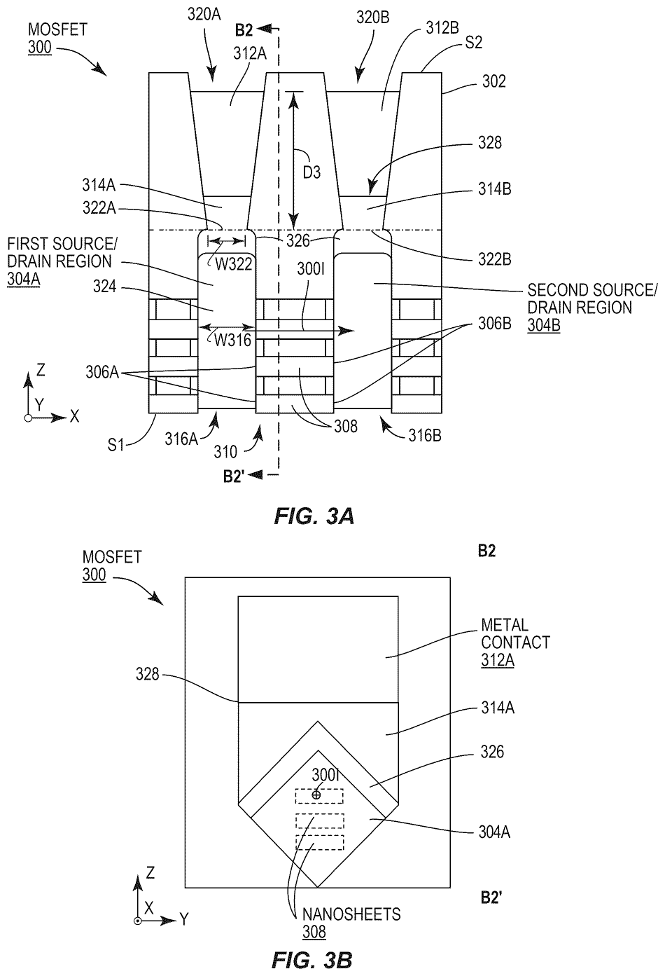

FIG. 3A is a cross-sectional side view of an exemplary MOSFET 300 formed in a semiconductor substrate 302 and including a first source/drain region 304A and a second source/drain region 304B at opposite ends 306A, 306B of nanosheets 308. A side view of the cross-section B2-B2′ of the MOSFET 300 is shown in FIG. 3B. The MOSFET 300 may be the second transistor 104 in FIG. 1. In some examples, the MOSFET 300 is a P-channel or P-type transistor (e.g., PFET) in which current flow tends to be lower than in similarly sized N-channel or N-type transistors (NFETs). The view in FIG. 3A is in a first direction (X-axis direction) orthogonal to a flow of current 300I in a second (Y-axis) direction through the plurality of nanosheets 308 in a channel region 310. The current 300I may run either way (e.g., left or right in FIG. 3A) in the first direction between the first source/drain region 304A and the second source/drain region 304B, depending on which is configured as the source, and which is the drain in a circuit configuration.

As in the view in FIG. 2A, the MOSFET 300 in FIG. 3A is in an inverted orientation with a first side S1 of the semiconductor substrate 302, on which frontside metallization layers would be formed but are not shown, on the bottom in FIG. 3A. A second side S2 of the semiconductor substrate 302, including metal contacts 312A, 312B, is on the top of FIG. 3A. The metal contacts 312A, 312B extend in the third (Z-axis) direction from the first source/drain region 304A and the second source/drain region 304B, respectively. The MOSFET 300 also includes germanide layers 314A, 314B disposed between the source/drain regions 304A, 304B and the metal contacts 312A, 312B to provide a lower resistance interface. The germanide layers 314A, 314B may be formed at a lower temperature range (e.g., less than 400° C.) than the silicide layers in FIGS. 2A and 2B, in a process that may be employed in backend processing to lower a resistance of an electrical path compared to the silicide layer 124 shown in FIG. 1.

The source/drain regions 304A, 304B may be formed by epitaxial growth in first voids 316A, 316B at each end of the nanosheets 308. The first voids 316A, 316B are formed in the semiconductor substrate 302, for example by a subtractive process, such as etching, and extend from the second side S2 of the semiconductor substrate 302. Subsequently, the MOSFET 300 may be inverted to be in the orientation shown in FIG. 3A and second voids 320A, 320B are formed in the semiconductor substrate 302. The second voids 320A, 320B are collinear or aligned with the first voids 316A, 316B in a direction orthogonal to the first side S1. The second voids 320A, 320B extend through the semiconductor substrate 302 to the first voids 316A, 316B where openings 322A, 322B into the first voids 316A, 316B are created. The openings 322A, 322B may have a width W322 that is narrower in the first direction than a width W316 of the first voids 316A, 316B. The extraction process employed for creating (e.g., etching) the second voids 320A, 320B in the semiconductor substrate 302 may extend beyond a depth D3. In some situations, extension of the voids 320A, 320B causes damage to or removal of some epitaxial material 324 of the first and second source/drain regions 304A, 304B through the openings 322A, 322B.

A germanium layer 326 may be formed through the openings 322A, 322B on recessed or damaged portions of the epitaxial material 324. In some examples, the germanium layer 326 may be epitaxially grown on the recessed/damaged epitaxial material 324 to heal or at least reduce damage to the epitaxial material 324 and provide a low electrical resistance between the source/drain regions 304A, 304B, and the metal contacts 312A, 312B. In this example, the germanium layer 326 may fill any space in the first voids 316A, 316B where the epitaxial material 324 of the source/drain regions 304A, 304B has been recessed, whether intentionally or unintentionally.

To form the germanide layers 314A, 314B, additional germanium may be deposited on the germanium layer 326, and a metal 328 is deposited or formed in some manner on the germanium layer 326. The germanide layers 314A, 314B may be formed in a process in which temperatures of the MOSFET 300 are raised to a maximum of less than 400° C. and may be about 350° C., which allows the metal 328 and the germanium in the openings 322A, 322B to combine (e.g., by diffusion). The resultant germanide layers 314A, 314B, and any remaining germanium layer 326 and metal 328 provide a low resistance path between the first and second source/drain regions 304A, 304B and the metal contacts 312A, 312B. In some examples, the metal 328 may be nickel (Ni). In some examples, the metal 328 may be cobalt (Co) or tungsten (W). The metal contact 312A may be copper (Cu) formed directly or indirectly on the germanide layer 314A. In some examples, an intermediate metal, such as cobalt, molybdenum, or tungsten, may be formed directly or indirectly on the germanide layer 314A, and copper may be formed on the intermediate metal.

FIG. 3B is a side view of the cross-section B2-B2′ through the first source/drain region 304A of the MOSFET 300 in FIG. 3A shown in the second direction (Y-axis) parallel to current flow 300I through the nanosheets 308. The first source/drain region 304A may be formed by epitaxial growth from the nanosheets 308. As shown, some of the germanium layer 326 formed on the first source/drain region 304A remains after the process (e.g., annealing) for forming the germanide layer 314A. In some examples, the germanide layer 314A may have a gradient of respective concentrations of germanium and metal, where a concentration of germanium is highest adjacent to the germanium layer 326, and a concentration of the metal 328 is highest adjacent to the metal contacts 312A, 312B. Although the discussion above is directed to the MOSFET 300 in FIGS. 3A and 3B, a germanide layer such as the germanide layer 314A may be employed in backside contacts in ICs having other types of FETs and/or types of transistors other than FETs.

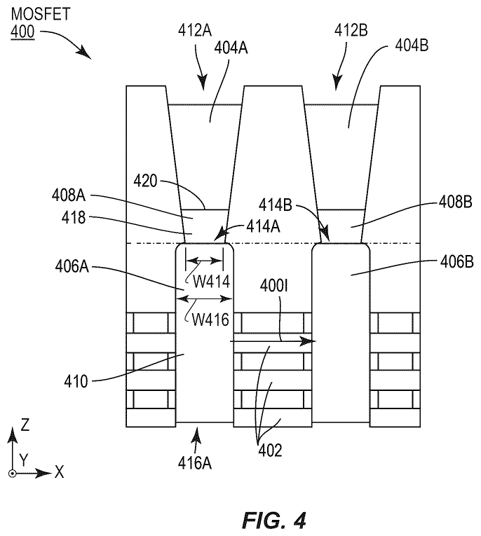

FIG. 4 is a cross-sectional side view of a second example of a MOSFET 400 from a perspective in the first (X-axis) direction orthogonal to a direction of flow of current 400I through nanosheets 402, corresponding to the perspective of the MOSFET 300 in FIG. 3A. The MOSFET 400 may be the second transistor 104 in FIG. 1. The MOSFET 400 also has a lower resistance between metal contacts 404A, 404B and source/drain regions 406A, 406B provided by germanide layers 408A, 408B. FIG. 4 is provided to show an example in which epitaxial material 410 is not damaged or is only slightly damaged/removed in the extraction process employed to form voids 412A, 412B. In particular, the epitaxial material 410 of the first and second source/drain regions 406A, 406B extends to openings 414A, 414B at which the epitaxial material 410 is exposed through the voids 412A, 412B. A width W414 of the opening 414A in the first direction is less than a width W416 of a void 416A in which the first source/drain region 406A is formed.

Formation of the germanide layers 408A, 408B proceeds as described above with respect to FIG. 3A. Since the epitaxial material 410 of the first and second source/drain regions 406A, 406B are not damaged in this case, the epitaxially grown germanium layer 326 used in FIG. 3A to heal the epitaxial material 410 is not included here. Germanium 418 may be deposited on the epitaxial material 410 and a metal 420 or combination of metals is deposited or formed on the germanium 418. In a process reaching a maximum of less than 400° C., for example that may be about 350° C., the germanium 418 and metal 420 may combine to form the germanide layers 408A, 408B.

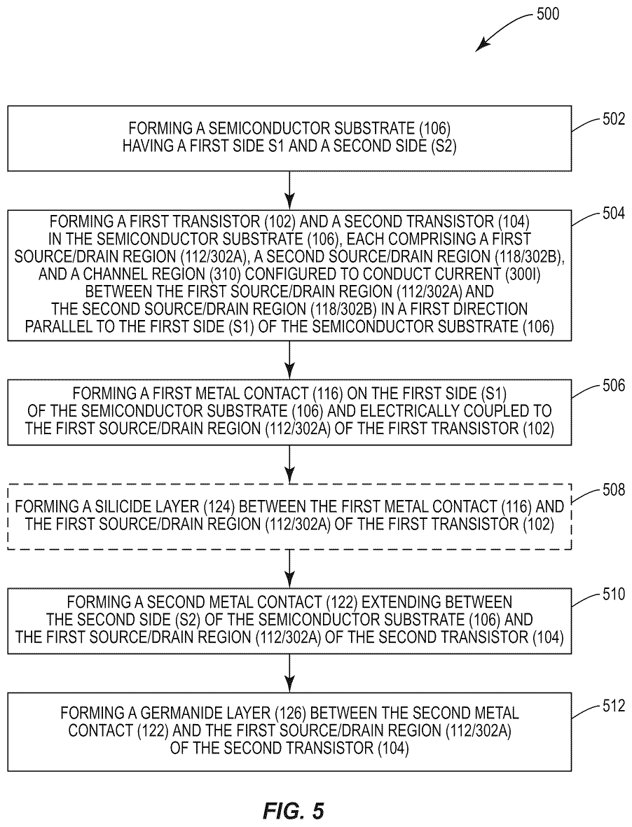

FIG. 5 is a flowchart of an exemplary process 500 for manufacturing the IC 100 of FIG. 1, including the MOSFET 300 in FIGS. 3A and 3B. Thus, the method 500 is described with additional reference to FIGS. 1, 3A, and 3B. The method 500 includes forming a semiconductor substrate 106 having a first side S1 and a second side S2 (block 502). The method 500 includes forming a first transistor 102 and a second transistor 104 in the semiconductor substrate 106, each comprising a first source/drain region 112/302A, a second source/drain region 118/302B, and a channel region 310 configured to conduct current 300I between the first source/drain region 112/302A and the second source/drain region 118/302B in a first direction parallel to the first side S1 of the semiconductor substrate 106 (block 504). The method 500 includes forming a first metal contact 116 on the first side S1 of the semiconductor substrate 106 and electrically coupled to the first source/drain region 112/302A of the first transistor 102 (block 506). The method 500 optionally includes forming a silicide layer 124 between the first metal contact 116 and the first source/drain region 112/302A of the first transistor 102 (block 508). The method further includes forming a second metal contact 122 extending between the second side S2 of the semiconductor substrate 106 and the first source/drain region 112/302A of the second transistor 104 (block 510), and forming a germanide layer 126 between the second metal contact 122 and the first source/drain region 112/302A of the second transistor 104 (block 512).

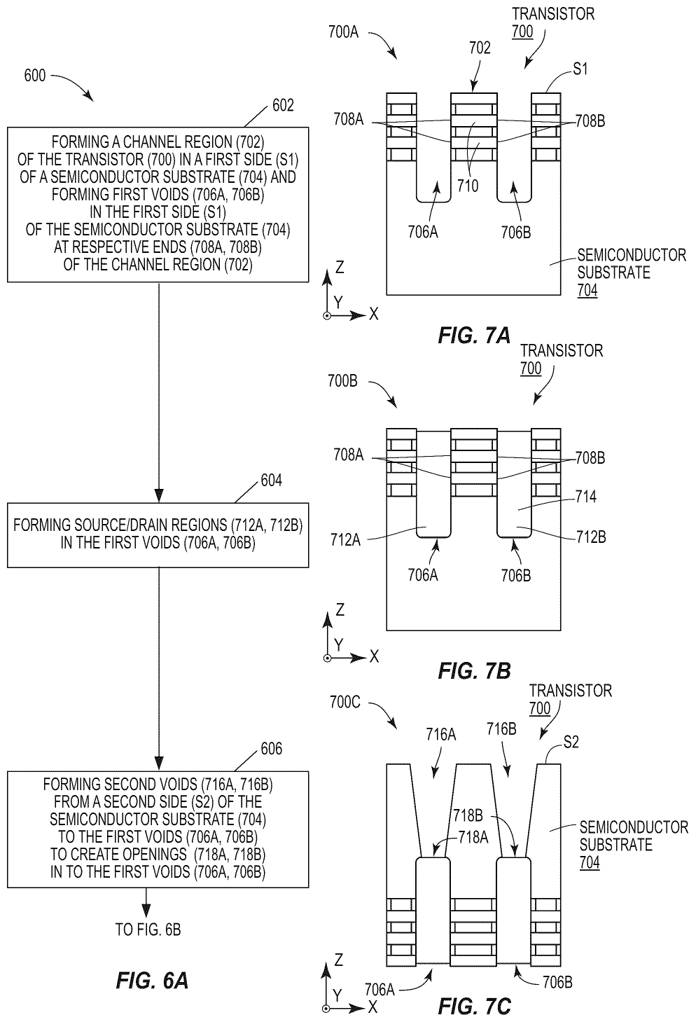

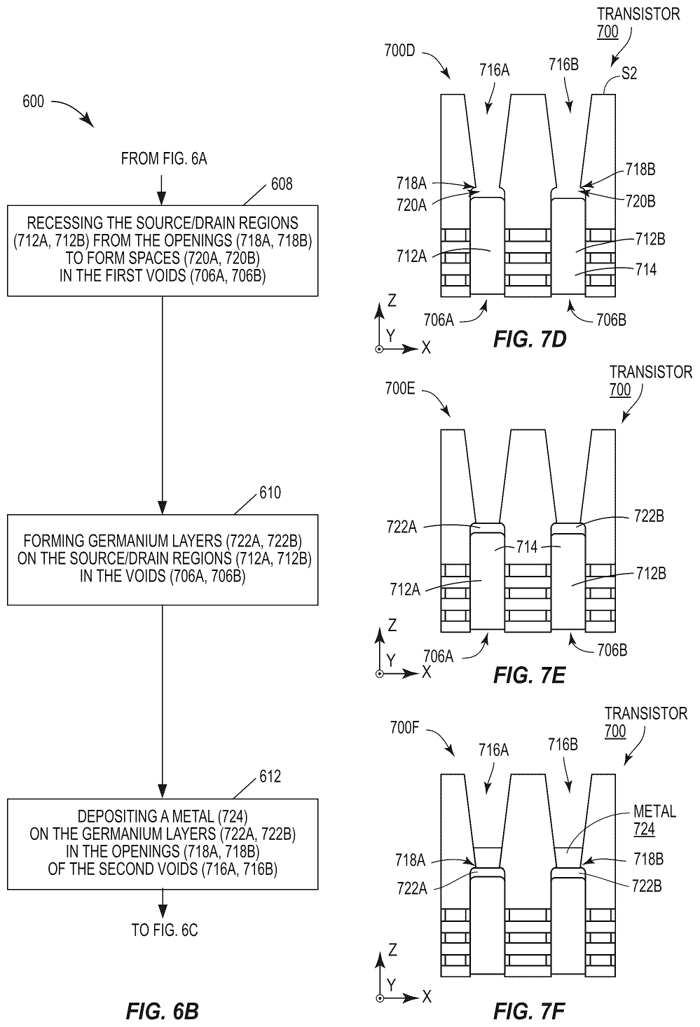

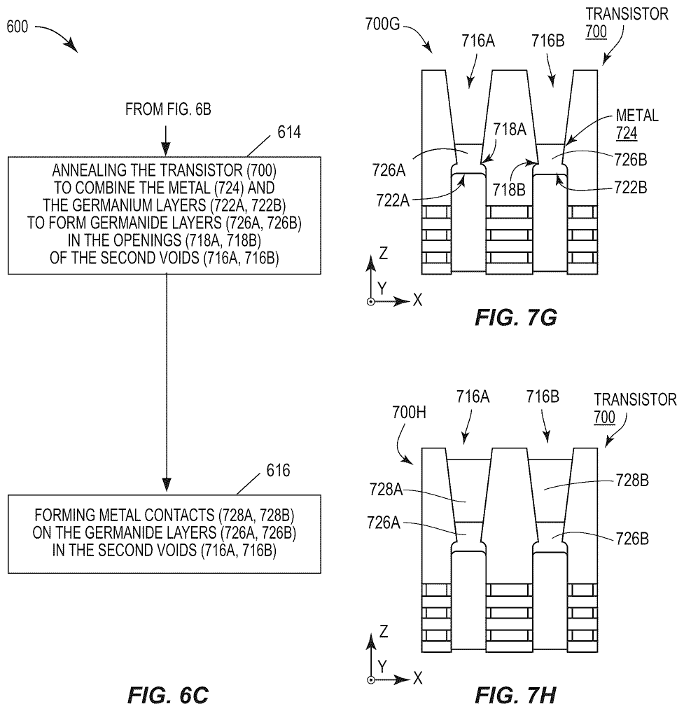

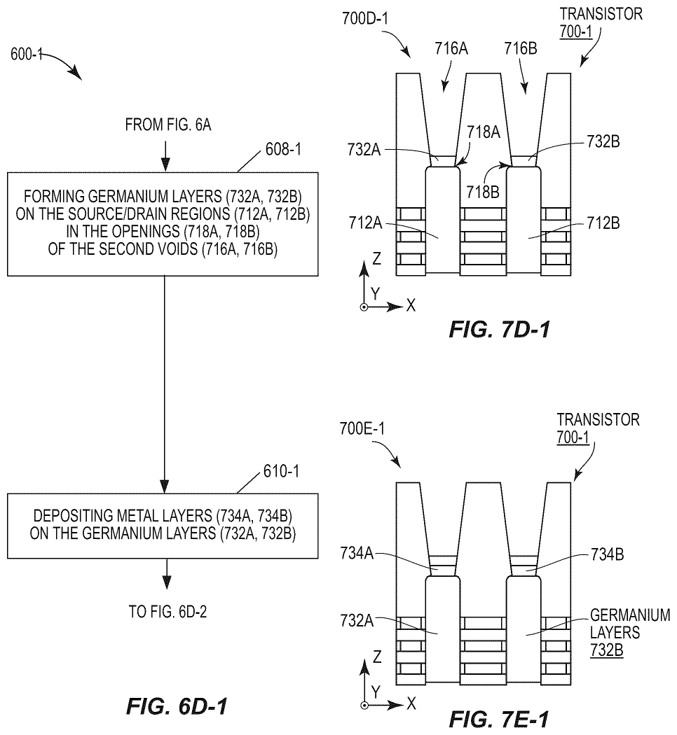

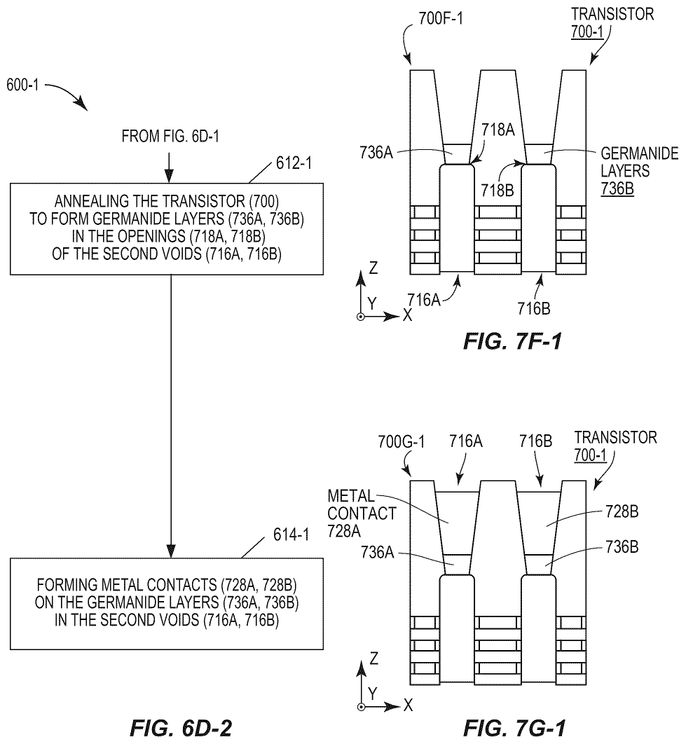

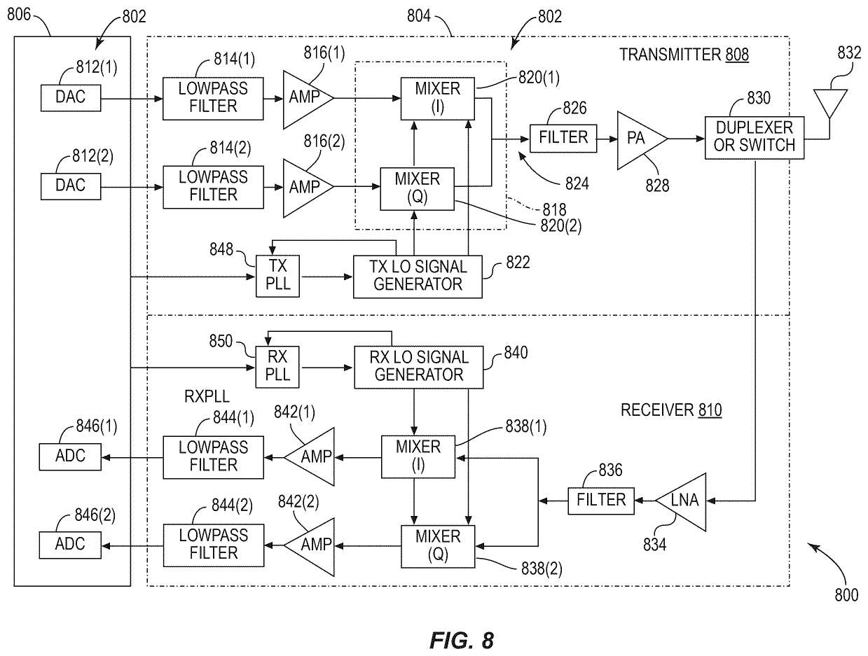

FIGS. 6A-6C are a flowchart of an exemplary process 600 for fabricating a transistor 700, which may be the MOSFET 300 in FIGS. 3A and 3B and the second transistor 104 in the IC 100 in FIG. 1. FIGS. 7A-7H are illustrations of the transistor 700 at stages 700A-700H of the exemplary process 600 described in FIGS. 6A-6C.

In FIG. 6A, the method 600 includes, as illustrated in fabrication stage 700A, forming a channel region 702 of the transistor 700 in a first side S1 of a semiconductor substrate 704 and forming first voids 706A, 706B in the first side S1 of the semiconductor substrate 704 at respective ends 708A, 708B of the channel region 702 (block 602). In the example in fabrication stage 700A, the channel region 702 comprises nanosheets 710 but may alternatively comprise fins, nano-wires, etc. Frontside metallization layers (not shown) may be formed on the first side S1 of the semiconductor substrate 704 but are excluded from FIGS. 7B-7H.

The method 600 in FIG. 6A includes, as illustrated in fabrication stage 700B, forming source/drain regions 712A, 712B in the first voids 706A, 706B (block 604). The source/drain regions 712A, 712B may be epitaxial material 714 grown from ends 708A, 708B of the channel region 702.

The method 600 in FIG. 6A includes, as illustrated in manufacturing stage 700C, forming second voids 716A, 716B from a second side S2 of the semiconductor substrate 704 to the first voids 706A, 706B to create openings 718A, 718B into the first voids 706A, 706B (block 606). The transistor 700 shown in FIGS. 7C-7H is inverted with respect to FIGS. 7A-7B.

In FIG. 6B, the method 600 includes, as illustrated in manufacturing stage 700D, recessing the source/drain regions 712A, 712B from the openings 718A, 718B to form spaces 720A, 720B in the first voids 706A, 706B (block 608). The spaces 720A, 720B may be formed unintentionally during the extractive process that created the second voids 716A, 716B, or may be formed intentionally, such as with an etchant specific to the epitaxial material 714.

The method 600 in FIG. 6B further includes, as illustrated in manufacturing stage 700E, forming germanium layers 722A, 722B on the source/drain regions 712A, 712B in the voids 706A, 706B (block 610). The germanium layers 722A, 722B may be epitaxial germanium layers that form low resistance interfaces to the epitaxial material 714, healing damaged portions of the epitaxial material 714.

The method 600 in FIG. 6F also includes, as illustrated in manufacturing stage 700F, depositing a metal 724 on the germanium layers 722A, 722B in the openings 718A, 718B of the second voids 716A, 716B (block 612).

In FIG. 6C, the method 600 includes, as illustrated in manufacturing stage 700G, annealing the transistor 700 to combine the metal 724 and the germanium layers 722A, 722B to form germanide layers 726A, 726B in the openings 718A, 718B of the second voids 716A, 716B (block 614).

The method 600 in FIG. 6C also includes, as illustrated in manufacturing stage 700H, forming metal contacts 728A, 728B on the germanide layers 726A, 726B in the second voids 716A, 716B (block 616).

FIGS. 6D-1-6G-1 are a flowchart of an alternative exemplary process 600-1 for fabricating a transistor 700-1, which may be the MOSFET 400 in FIG. 4 and the second transistor 104 in the IC 100 in FIG. 1. FIGS. 7D-1-7G-1 are illustrations of the transistor 700-1 at fabrication stages 700D-1-700G-1 of the exemplary process 600 described in FIGS. 6D-1-6G-1. The fabrication stages 700D-1-700G-1 are intended to follow (come after) the fabrication stages 700A-700C above and provide an alternative to the fabrication stages 700D-700H.

In FIG. 6D-1, the method 600-1 includes, as illustrated in manufacturing stage 700D-1, forming germanium layers 732A, 732B on the source/drain regions 712A, 712B in the openings 718A, 718B of the second voids 716A, 716B (block 608-1).

The method 600-1 in FIG. 6D-1 also includes, as illustrated in manufacturing stage 700E-1, depositing metal layers 734A, 734B on the germanium layers 732A, 732B (block 610-1).

In FIG. 6D-2, the method 600-1 includes, as illustrated in manufacturing stage 700F-1, annealing the transistor 700-1 to form germanide layers 736A, 736B in the openings 718A, 718B of the second voids 716A, 716B (block 612-1).

Also in FIG. 6D-2, the method 600-1 includes, as illustrated in manufacturing stage 700G-1, forming metal contacts 728A, 728B on the germanide layers 736A, 736B in the second voids 716A, 716B (block 614-1).

The transistors 700, 700-1 formed by either the stages 700A-700H or 700D-1-700G-1 have a lower resistance backside interface between the source/drain regions 712A, 712B and the metal contacts 728A, 728B than certain other transistors, such as the MOSFET 200 with silicide layers that have been formed at lower temperatures.

ICs in which the backside contacts are coupled to source/drain regions of transistors through germanide layers may be employed in any processor-based device. Examples of such processor-based devices, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

FIG. 8 illustrates an exemplary wireless communications device 800 that includes radio-frequency (RF) components formed from one or more ICs 802, wherein any of the ICs 802 may include backside contacts coupled to source/drain regions of transistors through germanide layers to provide a lower resistance interface as shown in FIGS. 3A, 3B, 4, 7A-7H and 7D-1-7G-1. The wireless communications device 800 may include or be provided in any of the above-referenced devices as examples. As shown in FIG. 8, the wireless communications device 800 includes a transceiver 804 and a data processor 806. The data processor 806 may include a memory to store data and program codes. The transceiver 804 includes a transmitter 808 and a receiver 810 that support bi-directional communications. In general, the wireless communications device 800 may include any number of transmitters 808 and/or receivers 810 for any number of communication systems and frequency bands. All or a portion of the transceiver 804 may be implemented on one or more analog ICs, RF ICs (RFICs), mixed-signal ICs, etc.

The transmitter 808 or the receiver 810 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage and then from IF to baseband in another stage for the receiver 810. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into the I and Q analog output signals (e.g., I and Q output currents) for further processing.

Within the transmitter 808, lowpass filters 814(1), 814(2) filter the I and Q analog output signals, respectively, to remove undesired signals caused by the prior digital-to-analog conversion. Amplifiers (AMPs) 816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals through mixers 820(1), 820(2) from a TX LO signal generator 822 to provide an upconverted signal 824. A filter 826 filters the upconverted signal 824 to remove undesired signals caused by the frequency up-conversion as well as noise in a receive frequency band. A power amplifier (PA) 828 amplifies the upconverted signal 824 from the filter 826 to obtain the desired output power level and provides a transmit RF signal. The transmit RF signal is routed through a duplexer or switch 830 and transmitted via an antenna 832.

In the receive path, the antenna 832 receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Down-conversion mixers 838(1), 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1), 842(2) and further filtered by lowpass filters 844(1), 844(2) to obtain I and Q analog input signals, which are provided to the data processor 806. In this example, the data processor 806 includes analog-to-digital converters (ADCs) 846(1), 846(2) for converting the analog input signals into digital signals to be further processed by the data processor 806.

In the wireless communications device 800 of FIG. 8, the TX LO signal generator 822 generates the I and Q TX LO signals used for frequency up-conversion, while the RX LO signal generator 840 generates the I and Q RX LO signals used for frequency down-conversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

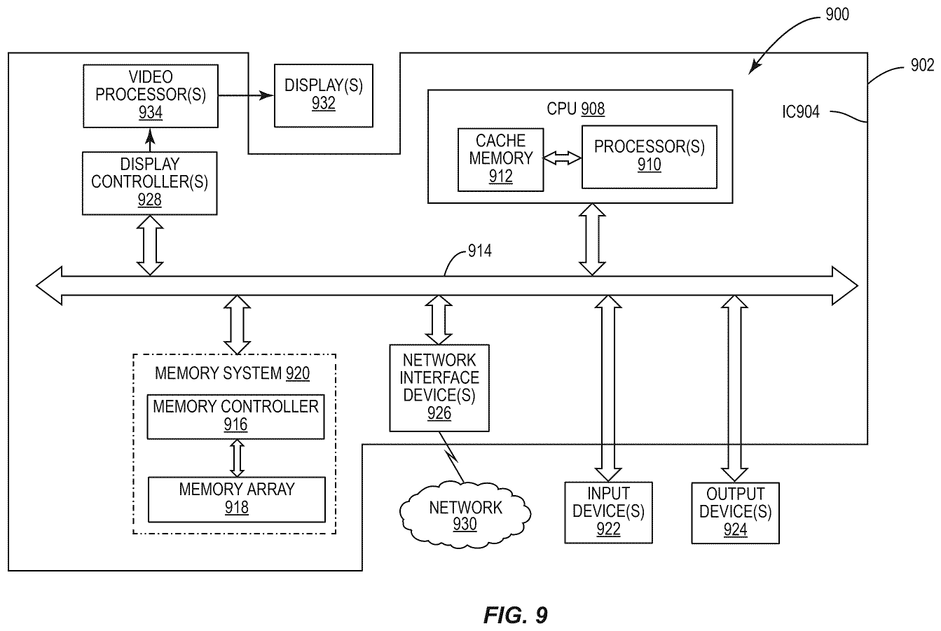

In this regard, FIG. 9 illustrates an example of a processor-based system 900 that can include ICs with backside contacts coupled to source/drain regions of transistors through germanide layers to provide a lower resistance interface, as shown in FIGS. 3A, 3B, 4, 7A-7H and 7D-1-7G-1. The processor-based system 900 includes a central processing unit (CPU) 908 that includes one or more processors 910, which may also be referred to as CPU cores or processor cores. The CPU 908 may have cache memory 912 coupled to the CPU 908 for rapid access to temporarily stored data. The CPU 908 is coupled to a system bus 914 and can intercouple master and slave devices included in the processor-based system 900. As is well known, the CPU 908 communicates with these other devices by exchanging address, control, and data information over the system bus 914. For example, the CPU 908 can communicate bus transaction requests to a memory controller 916, as an example of a slave device. Although not illustrated in FIG. 9, multiple system buses 914 could be provided, wherein each system bus 914 constitutes a different fabric.

Other master and slave devices can be connected to the system bus 914. As illustrated in FIG. 9, these devices can include a memory system 920 that includes the memory controller 916 and a memory array(s) 918, one or more input devices 922, one or more output devices 924, one or more network interface devices 926, and one or more display controllers 928, as examples. The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow an exchange of data to and from a network 930. The network 930 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 926 can be configured to support any type of communications protocol desired.

The CPU 908 may also be configured to access the display controller(s) 928 over the system bus 914 to control information sent to one or more displays 932. The display controller(s) 928 sends information to the display(s) 932 to be displayed via one or more video processor(s) 934, which processes the information to be displayed into a format suitable for the display(s) 932. The display(s) 932 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:
1. An integrated circuit (IC) comprising:
   a semiconductor substrate having a first side and a second side;
   a first transistor and a second transistor formed in the semiconductor substrate and
      each comprising:
      a first source/drain region;
      a second source/drain region; and
      a channel region between the first source/drain region and the second source/drain region;
   a first metal contact adjacent to the first side of the semiconductor substrate and electrically coupled to the first source/drain region of the first transistor;
   a second metal contact extending between the second side of the semiconductor substrate and the first source/drain region of the second transistor; and
   a germanide layer disposed between the second metal contact and the first source/drain region of the second transistor.
2. The IC of clause 1, further comprising a silicide layer disposed between the first metal contact and the first source/drain region.
3. the IC of clause 1 or clause 2, wherein:
   the first source/drain region of the second transistor is disposed in a first void having a first width in a first direction parallel to the first side of the semiconductor substrate, the first void extending in a second direction orthogonal to the first direction;
   the second metal contact is disposed in a second void extending in the second direction from the second side of the semiconductor substrate to an opening into the first void; and
   a second width of the opening in the first direction is less than the first width of the first void in the first direction.
4. The IC of clause 3, wherein the first void is collinear with the second void and extending in the second direction.
5. The IC of clause 3 or clause 4, further comprising a germanium layer disposed between the second metal contact and the germanide layer.
6. The IC of clause 5, wherein:
   the germanium layer is disposed in the first void between the opening and the first source/drain region of the second transistor; and
   the germanide layer is disposed in the second void between the opening and the second metal contact.
7. The IC of clause 5 or clause 6, wherein:
   the germanium layer is disposed in the second void between the opening and the second metal contact; and
   the germanide layer is disposed in the second void between the germanium layer and the second metal contact.
8. The IC of any of clause 5 to clause 7, wherein the germanide layer comprises germanium and nickel.
9. The IC of any of clause 1 to clause 8, further comprising at least one interconnect layer disposed on the second side of the semiconductor substrate, wherein the second metal contact is coupled to the at least one interconnect layer.
10. The IC of any of clause 1 to clause 9, wherein each of the first transistor and the second transistor comprises a field effect transistor (FET).
11. The IC of clause 10, wherein the channel region of the FET comprises a plurality of nanosheets extending in the first direction.
12. The IC of clause 11, wherein the FET comprises a p-channel FET (PFET).
13. The IC of any of clause 1 to clause 12, wherein:
   the first source/drain regions of the first transistor and the second transistor comprise silicon and germanium.
14. The IC of clause 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
15. A method of manufacturing an integrated circuit (IC), the method comprising:
   forming a semiconductor substrate having a first side and a second side;
   forming a first transistor and a second transistor in the semiconductor substrate,
      each comprising:
      a first source/drain region;
      a second source/drain region; and
      a channel region disposed between the first source/drain region and the second source/drain region;
   forming a first metal contact on the first side of the semiconductor substrate and electrically coupled to the first source/drain region of the first transistor;
   forming a second metal contact extending between the second side of the semiconductor substrate and the first source/drain region of the second transistor; and
   forming a germanide layer disposed between the second metal contact and the first source/drain region of the second transistor.
16. The method of clause 15, further comprising forming a silicide layer between the first metal contact and the first source/drain region of the first transistor.
17. The method of clause 15 or clause 16, wherein:
   forming the first source/drain region of the second transistor further comprises forming the first source/drain region of the second transistor in a first void that has a first width in the first direction and extends to the first side of the semiconductor substrate in a second direction orthogonal to the first direction; and
   forming the second metal contact further comprises forming a second void extending in the second direction from the second side of the semiconductor substrate to the first void,
   wherein an opening between the first void and the second void has a second width in the first direction less than the first width of the first void.
18. The method of clause 17, wherein:
   forming the second void further comprises recessing the first source/drain region of the second transistor away from the opening;
   depositing a germanium layer between the first source/drain region of the second transistor and the opening;
   depositing a first metal in the second void on the germanium layer adjacent to the opening; and
   annealing the IC at a temperature of less than four hundred (400) degrees Celsius.
19. The method of clause 18, wherein:
   forming the second metal contact further comprises disposing a second metal in the second void on the germanide layer, or
   depositing the first metal comprises depositing one of nickel, platinum, cobalt, tungsten, and titanium.
20. The method of clause 19, further comprising forming metallization layers adjacent to the first side of the semiconductor substrate before the forming the germanide layer.

What is claimed is:

1. An integrated circuit (IC) comprising:
a semiconductor substrate having a first side and a second side;
a first transistor and a second transistor formed in the semiconductor substrate and
each comprising:
a first source/drain region;
a second source/drain region; and
a channel region between the first source/drain region and the second source/drain region;
a first metal contact adjacent to the first side of the semiconductor substrate and electrically coupled to the first source/drain region of the first transistor;
a second metal contact extending between the second side of the semiconductor substrate and the first source/drain region of the second transistor; and
a germanide layer disposed between the second metal contact and the first source/drain region of the second transistor.

2. The IC of claim 1, further comprising a silicide layer disposed between the first metal contact and the first source/drain region.

3. The IC of claim 1, wherein:
the first source/drain region of the second transistor is disposed in a first void having a first width in a first direction parallel to the first side of the semiconductor substrate, the first void extending in a second direction orthogonal to the first direction;
the second metal contact is disposed in a second void extending in the second direction from the second side of the semiconductor substrate to an opening into the first void; and
a second width of the opening in the first direction is less than the first width of the first void in the first direction.

4. The IC of claim 3, wherein the first void is collinear with the second void and extending in the second direction.

5. The IC of claim 3, further comprising a germanium layer disposed between the second metal contact and the germanide layer.

6. The IC of claim 5, wherein:
the germanium layer is disposed in the first void between the opening and the first source/drain region of the second transistor; and
the germanide layer is disposed in the second void between the opening and the second metal contact.

7. The IC of claim 5, wherein:
the germanium layer is disposed in the second void between the opening and the second metal contact; and
the germanide layer is disposed in the second void between the germanium layer and the second metal contact.

8. The IC of claim 5, wherein the germanide layer comprises germanium and nickel.

9. The IC of claim 1, further comprising at least one interconnect layer disposed on the second side of the semiconductor substrate, wherein the second metal contact is coupled to the at least one interconnect layer.

10. The IC of claim 1, wherein each of the first transistor and the second transistor comprises a field effect transistor (FET).

11. The IC of claim 10, wherein the channel region of the FET comprises a plurality of nanosheets.

12. The IC of claim 11, wherein the FET comprises a p-channel FET (PFET).

13. The IC of claim 1, wherein:
the first source/drain region of the first transistor and the second transistor comprise silicon and germanium.

14. The IC of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

15. A method of manufacturing an integrated circuit (IC), the method comprising:
forming a semiconductor substrate having a first side and a second side;
forming a first transistor and a second transistor in the semiconductor substrate,
each comprising:
a first source/drain region;
a second source/drain region; and
a channel region disposed between the first source/drain region and the second source/drain region;
forming a first metal contact on the first side of the semiconductor substrate and electrically coupled to the first source/drain region of the first transistor;
forming a second metal contact extending between the second side of the semiconductor substrate and the first source/drain region of the second transistor; and
forming a germanide layer disposed between the second metal contact and the first source/drain region of the second transistor.

16. The method of claim 15, further comprising forming a silicide layer between the first metal contact and the first source/drain region of the first transistor.

17. The method of claim 15, wherein:
forming the first source/drain region of the second transistor further comprises forming the first source/drain region of the second transistor in a first void that has a first width in a first direction parallel to the first side of the semiconductor substrate and extends to the first side of the semiconductor substrate in a second direction orthogonal to the first direction; and
forming the second metal contact further comprises forming a second void extending in the second direction from the second side of the semiconductor substrate to the first void,
wherein an opening between the first void and the second void has a second width in the first direction less than the first width of the first void.

18. The method of claim 17, wherein:
forming the second void further comprises recessing the first source/drain region of the second transistor away from the opening;
depositing a germanium layer between the first source/drain region of the second transistor and the opening;
depositing a first metal in the second void on the germanium layer adjacent to the opening; and
annealing the IC at a temperature of less than four hundred (400) degrees Celsius.

19. The method of claim 18, wherein:
forming the second metal contact further comprises disposing a second metal in the second void on the germanide layer, or
depositing the first metal comprises depositing one of nickel, platinum, cobalt, tungsten, and titanium.

20. The method of claim 19, further comprising forming metallization layers adjacent to the first side of the semiconductor substrate before the forming the germanide layer.
